(19) United States
(12) Patent Application Publication
(10) Pub. No.: US 2026/0282755 A1
(43) Pub. Date: Sep. 17, 2026

(54) LIGHT DETECTION ELEMENT

(71) Applicant: TDK Corporation, Tokyo (JP)

(72) Inventors: Takekazu YAMANE, Tokyo (JP); Takeshi NOJIRI, Tokyo (JP); Tomohito MIZUNO, Tokyo (JP); Tetsuya SHIBATA, Tokyo (JP); Hideaki FUKUZAWA, Tokyo (JP)

(73) Assignee: TDK Corporation, Tokyo (JP)

(21) Appl. No.: 19/564,553

(22) Filed: Mar. 12, 2026

(30) Foreign Application Priority Data
Mar. 14, 2025 (JP) 2025-041750

(51) Int. Cl. H10N 50/10; G02B 1/00; H10N 50/80; H10N 59/00

(52) U.S. Cl. CPC H10N 50/10; G02B 1/002; H10N 50/80; H10N 59/00; G02B 2207/101

(57) ABSTRACT

A light detection element includes a first magnetic element and a second magnetic element, a first lens that irradiates incident light to the first magnetic element, and a second lens that irradiates incident light to the second magnetic element. The first lens and the second lens are made of metalenses having a plurality of nanostructures arranged two-dimensionally. In order to make the phases at the focal points of the first lens and the second lens different from each other, the size of the plurality of nanostructures in the first lens decreases as the distance from the optical center of the first lens increases in a predetermined region determined according to the distance from the optical center, and the size of the plurality of nanostructures in the second lens decreases as the distance from the optical center increases in a predetermined region determined according to the distance from the optical center.

### CROSS-REFERENCE TO RELATED APPLICATION

This application claims a priority, under the Paris Convention, to Japanese Patent Application No. 2025-041750 filed on Mar. 14, 2025, the entirety of which is incorporated herein by reference.

### TECHNICAL FIELD

The present disclosure relates to a light detection element.

### BACKGROUND

Photoelectric conversion elements such as light detection elements are used in various applications. For example, Japanese Patent Application Publication No. 2001-292107 describes a receiver device that receives an optical signal using a photodiode. The photodiode is, for example, a pn junction diode using a semiconductor pn junction, and converts light into an electrical signal. For example, U.S. Pat. No. 9,842,874 describes an optical sensor using a semiconductor pn junction and an image sensor using this optical sensor.

Furthermore, for example, Japanese Patent Application Publication No. 2022-69387 discloses an optical sensor using a magnetic element and a receiver device using this optical sensor, and Japanese Patent Application Publication No. 2023-110453 discloses a technology that combines an optical sensor using a magnetic element with a metalens.

As recognized by the present inventors, light detection elements using semiconductor pn junctions are widely used, but new light detection elements are required for further development. In addition, light detection elements are required to improve the S/N ratio in light detection. In order to improve the S/N ratio, it is possible to use multiple photosensitive magnetic elements. For example, one method is to arrange the magnetic elements in an array. In order to efficiently irradiate light to each of the multiple magnetic elements, it is desirable to use a method in which multiple lenses are used to irradiate light to the multiple magnetic elements. However, when multiple lenses are used, there is a concern that the light passing through adjacent lenses will interfere with each other and reinforce each other, making it difficult to irradiate the magnetic element with the desired light.

### SUMMARY

One aspect of the present disclosure provides the light detection element that comprises a first magnetic element and a second magnetic element, each of which comprises a first ferromagnetic layer, a second ferromagnetic layer, and a spacer layer sandwiched between the first ferromagnetic layer and the second ferromagnetic layer, a first lens consisting of a metalens having a plurality of nanostructures arranged two-dimensionally, which irradiates incident light to the first magnetic element, and a second lens consisting of a metalens having a plurality of nanostructures arranged two-dimensionally, which irradiates incident light to the second magnetic element, wherein the size of the plurality of nanostructures in the first lens in a planar view seen from the optical axis direction of the first lens decreases as the distance from the optical center of the first lens increases in each region defined by the discontinuity points of equation (1) as boundaries, and the size of the plurality of nanostructures in the second lens in a planar view seen from the optical axis direction of the second lens decreases as the distance from the optical center of the second lens increases in each region defined by the discontinuity points of equation (2) as boundaries.

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

(In the above equations (1) and (2), r is the distance from the origin, f is the focal length of the first lens and the second lens, λ is the wavelength of the incident light, φ is the phase, a₁ is the distance from the origin to the optical center of the first lens, a₂ is the distance from the origin to the optical center of the second lens, Δφ is the phase difference, and floor is the floor function.)

One aspect of the present disclosure provides the light detection element that comprises a plurality of magnetic elements, each of which comprises a first ferromagnetic layer, a second ferromagnetic layer, and a spacer layer sandwiched between the first ferromagnetic layer and the second ferromagnetic layer, and a plurality of lenses, each of which irradiates light onto a corresponding magnetic element among the plurality of magnetic elements, and the plurality of lenses are each composed of a metalens having a plurality of nanostructures arranged two-dimensionally. The size of the plurality of nanostructures in one lens of adjacent lenses in a plan view seen from the optical axis direction of the one lens becomes smaller as the distance from the optical center of the one lens increases in each region defined by the discontinuity points of equation (1) as boundaries, and the size of the plurality of nanostructures in the other lens of adjacent lenses in a plan view seen from the optical axis direction of the other lens becomes smaller as the distance from the optical center of the other lens increases in each region defined by the discontinuity points of equation (2) as boundaries.

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

(In the above equations (1) and (2), r is the distance from the origin, f is the focal length of the adjacent lenses, λ is the wavelength of the incident light, φ is the phase, a₁ is the distance from the origin to the optical center of one of the lenses, a₂ is the distance from the origin to the optical center of the other lens, Δφ is the phase difference, and floor is the floor function.)

### BRIEF DESCRIPTION OF DRAWINGS

FIG. 1 shows a diagram showing the configuration of a light detection element according to a first embodiment of the present disclosure.

FIG. 2 shows a partially enlarged cross-sectional view showing the configuration of the magnetic element shown in FIG. 1.

FIG. 3 shows a diagram showing how light is focused by a lens in the light detection element shown in FIG. 1.

FIG. 4 shows a perspective view showing the configuration of the pillars that make up the metalens.

FIG. 5 shows a graph showing the relationship between the diameter of the pillars and the phase of light passing through the pillars.

FIG. 6 shows a plan view showing the results of a simulation of the configuration of the metalens in FIG. 1, with boundaries, regions, etc. also shown.

FIG. 7A shows a plan view showing the results of a simulation of the light spot on the focal plane.

FIG. 7B shows a graph showing the results of the simulation.

FIG. 8A shows a plan view showing the configuration of a lense of a light detection element according to a second embodiment of the present disclosure.

FIG. 8B shows a plan view showing the configuration of a magnetic element.

FIG. 9 shows a plan view showing the configuration of a light spot formed by the lens of the light detection element of FIGS. 8A and 8B.

FIG. 10 shows a plan view showing the results of a simulation of the configuration of the metalens of FIGS. 8A and 8B.

FIG. 11 shows a partially enlarged plan view showing boundaries, regions, etc. of the simulation result of FIG. 10.

FIG. 12 shows a plan view showing the results of a simulation of the configuration of a modified example of the metalens of FIG. 1.

FIG. 13 shows a diagram showing a first configuration of a light detection element according to related art.

FIG. 14 shows a diagram showing how light is focused by a lens in the light detection element shown in FIG. 13.

FIG. 15 shows a plan view showing the results of a simulation of the configuration of the metalens of FIG. 13.

FIG. 16A shows a plan view showing the results of a simulation of a light spot on the focal plane of the metalens of FIG. 13.

FIG. 16B shows a graph showing the results of the simulation.

FIG. 17A shows a plan view showing the configuration of a lens of a light detecting element related to related art.

FIG. 17B shows a plan view showing the configuration of a magnetic element.

FIG. 18 shows a plan view showing the configuration of a light spot formed by the lens of the light detecting element of FIGS. 17A and 17B.

### DETAILED DESCRIPTION

According to the present disclosure, even when multiple lenses are used, it is possible to provide a light detection element with excellent S/N ratio in photodetection by suppressing the reinforcement of light intensity due to interference of light passing through adjacent lenses.

Hereinafter, an embodiment of the present disclosure will be described in detail with reference to the drawings.

Here, it should be noted that for ease of understanding, the scale of each part in the drawings may differ from the actual scale. In the xyz Cartesian coordinate system set in the drawings, the x-axis and γ-axis directions are horizontal, and the z-axis direction is vertical. The positive direction of the z-axis is also called the upward direction, and the negative direction of the z-axis is also called the downward direction, but this has nothing to do with the direction of gravity. In directions such as parallel, right angle, orthogonal, horizontal, vertical, up/down, left/right, deviations that do not impair the effect of the embodiment are allowed. In addition, “~” indicating a numerical range means that the numerical values written before and after it are included as the lower and upper limits.

First, the first embodiment of the present disclosure will be described.

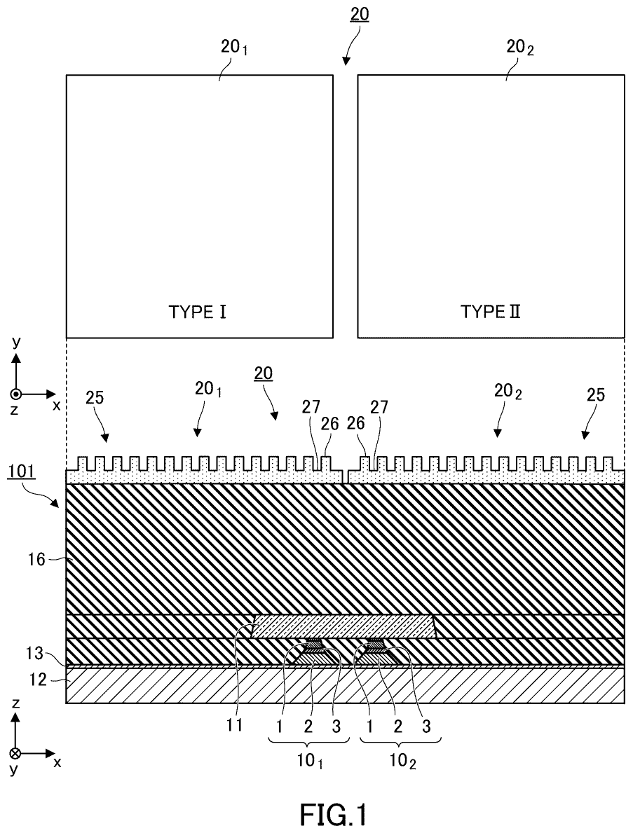

The lower diagram shown in FIG. 1 is a cross-sectional view showing the configuration of the light detection element 101 according to the first embodiment, and the upper diagram shown in FIG. 1 is a plan view showing the schematic configuration of the lens system of the light detection element 101. As shown in FIG. 1, the light detection element 101 includes a first magnetic element 10₁, a second magnetic element 10₂, a first lens 20₁, and a second lens 20₂. Hereinafter, the first magnetic element 10₁ and/or the second magnetic element 10₂ are also referred to as the “magnetic element 10”, and the first lens 20₁ and/or the second lens 20₂ are also referred to as the “lens 20”. The light detection element 101 may be columnar, for example, prismatic or cylindrical.

Light passing through the lens 20 is irradiated to the magnetic element 10. The magnetic element 10 detects the irradiated light and converts it into an electrical signal. This electrical signal is extracted using a first electrode 11 and a second electrode 12 respectively provided above and below the magnetic element 10.

The “light” described in this specification is not limited to the visible light, but may be the infrared light, which has a longer wavelength than the visible light, or the ultraviolet light, which has a shorter wavelength than the visible light. The wavelength of the visible light is, for example, 380 nm or more and less than 800 nm. The wavelength of the infrared light is, for example, 800 nm or more and 1 mm or less. The wavelength of the ultraviolet light is, for example, 200 nm or more and less than 380 nm.

Each component will be described hereinafter.

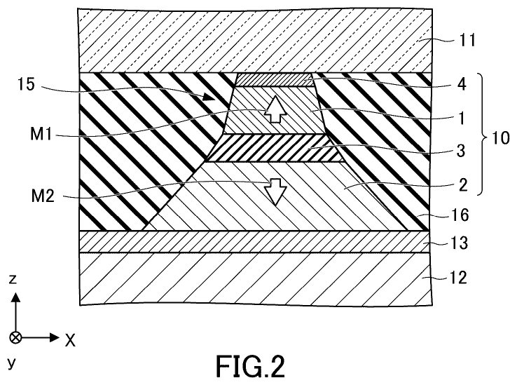

FIG. 2 is a partially enlarged cross-sectional view showing the configuration of the magnetic element 10 (first magnetic element 10₁, second magnetic element 10₂) in FIG. 1. As shown in FIG. 2, the magnetic element 10 includes at least a first ferromagnetic layer 1, a second ferromagnetic layer 2, and a spacer layer 3 sandwiched between the first ferromagnetic layer 1 and the second ferromagnetic layer 2. In FIG. 2, the second ferromagnetic layer 2, the spacer layer 3, the first ferromagnetic layer 1, and the cap layer 4 are stacked in this order in the positive direction of the z-axis to form a laminate 15. The laminate 15 constituting the magnetic element 10 may further include other layers such as a third ferromagnetic layer, a buffer layer, a seed layer, a magnetic coupling layer, and a perpendicular magnetization induction layer as necessary.

As shown in FIG. 1 and FIG. 2, a first electrode 11 is formed on the lens 20 side of the laminate 15, and a second electrode 12 is formed on the opposite side of the laminate 15 to the lens 20 via a cap layer 13. The magnetic element 10 may include the first electrode 11, the second electrode 12, the cap layer 13, the insulating layer 16, and the like in addition to the laminate 15. The cap layer 4 is located between the first ferromagnetic layer 1 and the first electrode 11, and the cap layer 13 is located between the second ferromagnetic layer 2 and the second electrode 12. The insulating layer 16 is formed between the lens 20 and the cap layer 13 or the second electrode 12, and is provided so as to cover the periphery of the laminate 15 and the first electrode 11.

The magnetic element 10 is, for example, a magnetic tunnel junction (MTJ) element in which the spacer layer 3 is made of an insulating material. In this case, the magnetic element 10 can exhibit a tunnel magnetoresistance (TMR: Tunnel Magneto Resistance) effect. The resistance value of the magnetic element 10 changes when irradiated with light from the outside. The resistance value of the magnetic element 10 in the z-axis direction (resistance value when a current is passed in the z-axis direction) changes according to the relative change between the state of magnetization M1 of the first ferromagnetic layer 1 and the state of magnetization M2 of the second ferromagnetic layer 2. For example, the resistance value of the magnetic element 10 in the z-axis direction changes according to the change in the relative angle between the direction of magnetization M1 of the first ferromagnetic layer 1 and the direction of magnetization M2 of the second ferromagnetic layer 2. Also, for example, the resistance value of the magnetic element 10 in the z-axis direction changes according to the change in the magnitude of magnetization M1 of the first ferromagnetic layer 1.

Furthermore, for example, if the spacer layer 3 is made of metal, the magnetic element 10 can exhibit a giant magnetoresistance (GMR) effect. Such an element is called a GMR element. Even when the magnetic element 10 is a GMR element, the resistance value in the z-axis direction (resistance value when a current is passed in the z-axis direction) changes according to the relative change between the state of magnetization M1 of the first ferromagnetic layer 1 and the state of magnetization M2 of the second ferromagnetic layer 2. The magnetic element 10 may be called an MTJ element, a GMR element, or the like, depending on the material of the spacer layer 3, but is also collectively called a magnetoresistance effect element. The total thickness of the magnetic element 10 is, for example, 15 nm to 40 nm.

The magnetic element 10 may have a ferromagnetic material whose magnetization state changes when irradiated with light, and the resistance value may change with the change in the magnetization state. The magnetic element 10 may be, for example, an anisotropic magnetoresistance (AMR) effect element, a colossal magnetoresistance (CMR) effect element, or the like, in addition to the above-mentioned MTJ element and GMR element.

The magnetic element 10 is disposed at the focal position of the light in the band of use focused by the lens 20. The focal position of the light in the band of use preferably overlaps, for example, with the first ferromagnetic layer 1. For example, when the visible light is used, the magnetic element 10 is disposed at the focal position of the light in a specific wavelength range of 380 nm or more and less than 800 nm. For example, when the infrared light is used, the magnetic element 10 is disposed at the focal position of the light in a specific wavelength range of 800 nm or more and less than 1 mm. For example, when the ultraviolet light is used, the magnetic element 10 is disposed at the focal position of the light in a specific wavelength range of 200 nm or more and less than 380 nm.

The first ferromagnetic layer 1 is a light detection layer whose magnetization state changes when light is irradiated from the outside. The first ferromagnetic layer 1 is also called a magnetization free layer. The magnetization free layer is a layer containing a magnetic material whose magnetization state changes when a specific external energy is applied. The specific external energy is, for example, light irradiated from the outside, a current flowing in the z-axis direction of the magnetic element 10, an external magnetic field, etc. The magnetization M1 of the first ferromagnetic layer 1 changes state depending on the intensity of the irradiated light.

The first ferromagnetic layer 1 contains a ferromagnetic material. The first ferromagnetic layer 1 contains at least one of magnetic elements such as Co, Fe, or Ni. The first ferromagnetic layer 1 may contain elements such as B, Mg, Hf, Gd, etc. in addition to the magnetic elements as described above. The first ferromagnetic layer 1 may be, for example, an alloy containing a magnetic element and a non-magnetic element. The first ferromagnetic layer 1 may be composed of multiple layers. The first ferromagnetic layer 1 may be, for example, a CoFeB alloy, a laminate in which a CoFeB alloy layer is sandwiched between Fe layers, or a laminate in which a CoFeB alloy layer is sandwiched between CoFe layers. In general, “ferromagnetic” includes “ferrimagnetic”. The first ferromagnetic layer 1 may exhibit ferrimagnetic properties. Alternatively, the first ferromagnetic layer 1 may exhibit ferromagnetic properties that are not ferrimagnetic. For example, a CoFeB alloy exhibits ferromagnetic properties that are not ferrimagnetic.

The first ferromagnetic layer 1 may be an in-plane magnetized film having an easy axis of magnetization in the in-plane direction (any direction in the xy plane) or a perpendicular magnetized film having an easy axis of magnetization in the direction perpendicular to the film plane (z-axis direction).

The film thickness of the first ferromagnetic layer 1 is, for example, 1 nm to 5 nm. The thickness of the first ferromagnetic layer 1 is preferably, for example, 1 nm to 2 nm. When the first ferromagnetic layer 1 is a perpendicular magnetization film, if the thickness of the first ferromagnetic layer 1 is thin, the perpendicular magnetic anisotropy application effect from the layers above and below the first ferromagnetic layer 1 is strengthened, and the perpendicular magnetic anisotropy of the first ferromagnetic layer 1 is enhanced. In other words, if the perpendicular magnetic anisotropy of the first ferromagnetic layer 1 is high, the force that causes the magnetization M1 to return to the z-axis direction is strengthened. On the other hand, if the thickness of the first ferromagnetic layer 1 is thick, the perpendicular magnetic anisotropy application effect from the layers above and below the first ferromagnetic layer 1 is relatively weak, and the perpendicular magnetic anisotropy of the first ferromagnetic layer 1 is weakened.

If the thickness of the first ferromagnetic layer 1 is thin, the volume of the ferromagnetic body becomes small, and if it is thick, the volume of the ferromagnetic body becomes large. The responsiveness of the magnetization of the first ferromagnetic layer 1 when external energy is applied is inversely proportional to the product (KuV) of the magnetic anisotropy (Ku) and the volume (V) of the first ferromagnetic layer 1. In other words, as the product of the magnetic anisotropy and the volume of the first ferromagnetic layer 1 decreases, the responsiveness to light increases. From this perspective, in order to increase the responsiveness to light, it is preferable to appropriately design the magnetic anisotropy of the first ferromagnetic layer 1 and then reduce the volume of the first ferromagnetic layer 1.

If the film thickness of the first ferromagnetic layer 1 is thicker than 2 nm, an insertion layer made of, for example, Mo or W may be provided in the first ferromagnetic layer 1. In other words, the first ferromagnetic layer 1 may be a laminate in which a ferromagnetic layer, an insertion layer, and a ferromagnetic layer are stacked in this order in the z-axis direction. The perpendicular magnetic anisotropy of the entire first ferromagnetic layer 1 is increased by the interface magnetic anisotropy at the interface between the insertion layer and the ferromagnetic layer. The film thickness of the insertion layer is, for example, 0.1 nm to 1.0 nm.

The second ferromagnetic layer 2 is a magnetization fixed layer. The magnetization fixed layer is a layer made of a magnetic material in which the state of magnetization is less likely to change than the magnetization free layer when a predetermined external energy is applied. For example, the magnetization direction of the magnetization fixed layer is less likely to change than the magnetization free layer when a predetermined external energy is applied. Also, for example, the magnitude of magnetization of the magnetization fixed layer is less likely to change than the magnetization free layer when a predetermined external energy is applied. The coercive force of the second ferromagnetic layer 2 is, for example, greater than the coercive force of the first ferromagnetic layer 1. The second ferromagnetic layer 2 has an easy magnetization axis in the same direction as the first ferromagnetic layer 1. The second ferromagnetic layer 2 may be an in-plane magnetization film or a perpendicular magnetization film.

The material constituting the second ferromagnetic layer 2 is, for example, the same as that of the first ferromagnetic layer 1. The second ferromagnetic layer 2 may be, for example, a multilayer film in which Co having a thickness of 0.4 nm to 1.0 nm and Pt having a thickness of 0.4 nm to 1.0 nm are alternately stacked several times. The second ferromagnetic layer 2 may be, for example, a laminate in which Co having a thickness of 0.4 nm to 1.0 nm, Mo having a thickness of 0.1 nm to 0.5 nm, CoFeB alloy having a thickness of 0.3 nm to 1.0 nm, and Fe having a thickness of 0.3 nm to 1.0 nm are stacked in this order.

The spacer layer 3 is a layer disposed between the first ferromagnetic layer 1 and the second ferromagnetic layer 2. The spacer layer 3 is composed of a layer composed of a conductor, an insulator, or a semiconductor, or a layer containing a current-carrying point composed of a conductor in an insulator. The spacer layer 3 is, for example, a nonmagnetic layer. The thickness of the spacer layer 3 can be adjusted according to the orientation of the magnetization of the first ferromagnetic layer 1 and the magnetization of the second ferromagnetic layer 2 in the initial state described later.

When the spacer layer 3 is made of an insulating material, materials containing aluminum oxide, magnesium oxide, titanium oxide, silicon oxide, etc. can be used as the material of the spacer layer 3. These insulating materials may also contain elements such as Al, B, Si, Mg, and magnetic elements such as Co, Fe, Ni. A high magnetoresistance change rate can be obtained by adjusting the thickness of the spacer layer 3 so that a high TMR effect is generated between the first ferromagnetic layer 1 and the second ferromagnetic layer 2. In order to efficiently utilize the TMR effect, the thickness of the spacer layer 3 may be about 0.5 nm to 5.0 nm, or about 1.0 nm to 2.5 nm.

When the spacer layer 3 is made of a non-magnetic conductive material, conductive materials such as Cu, Ag, Au, and Ru can be used. To efficiently utilize the GMR effect, the thickness of the spacer layer 3 may be about 0.5 nm to 5.0 nm, or about 2.0 nm to 3.0 nm.

When the spacer layer 3 is made of a non-magnetic semiconductor material, materials such as zinc oxide, indium oxide, tin oxide, germanium oxide, gallium oxide, or indium tin oxide (ITO) can be used. In this case, the thickness of the spacer layer 3 may be about 1.0 nm to 4.0 nm.

When a layer including a current-carrying point formed by a conductor in a non-magnetic insulator is used as the spacer layer 3, a structure including a current-carrying point formed by a non-magnetic conductor such as Cu, Au, or Al in a non-magnetic insulator made of aluminum oxide or magnesium oxide may be used. The conductor may also be made of magnetic elements such as Co, Fe, or Ni. In this case, the thickness of the spacer layer 3 may be about 1.0 nm to 2.5 nm. The current-carrying point is, for example, a columnar body with a diameter of 1 nm to 5 nm when viewed from a direction perpendicular to the film surface.

The cap layer 4 is provided between the first ferromagnetic layer 1 and the first electrode 11. The cap layer 4 may include a perpendicular magnetization induction layer (not shown) that is laminated on the first ferromagnetic layer 1 and in contact with the first ferromagnetic layer 1. The cap layer 4 prevents damage to the lower layer during the manufacturing process and enhances the crystallinity of the lower layer during annealing. The thickness of the cap layer 4 is, for example, 10 nm or less so that the first ferromagnetic layer 1 is irradiated with sufficient light.

The insulating layer 16 is provided between the lens 20 (first lens 20₁, second lens 20₂) and the second electrode 12 or the cap layer 13, and is formed so as to cover the periphery of the magnetic element 10 (first magnetic element 10₁, second magnetic element 10₂) and the first electrode 11. The insulating layer 16 is, for example, an oxide, nitride, or oxynitride of Si, Al, or Mg. The insulating layer 16 is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), etc. The insulating layer 16 transmits light in the used band. The insulating layer 16 preferably transmits, for example, 80% or more of the light in the used wavelength range.

The first electrode 11 is, for example, disposed on the lens 20 side of the magnetic element 10. Incident light is irradiated to the magnetic element 10 from the first electrode 11 side, and is irradiated to at least the first ferromagnetic layer 1. The first electrode 11 is made of a material having electrical conductivity. The first electrode 11 is, for example, a transparent electrode that is transparent to light in the used wavelength range. The first electrode 11 preferably transmits, for example, 80% or more of the light in the used wavelength range. The first electrode 11 is, for example, an oxide such as indium tin oxide (ITO), indium zinc oxide (IZO), zinc oxide (ZnO), or indium gallium zinc oxide (IGZO). The first electrode 11 may be configured to have a plurality of columnar metals in a transparent electrode material of these oxides.

It is not essential to use the above-mentioned transparent electrode material for the first electrode 11, and a metal material such as Au, Cu, or Al may be used with a thin film thickness to allow the irradiated light to reach the first ferromagnetic layer 1. When a metal is used as the material for the first electrode 11, the film thickness of the first electrode 11 is, for example, 3 nm to 10 nm. The first electrode 11 may also have an anti-reflection film on the irradiation surface to which light is irradiated.

The second electrode 12 is made of a material having electrical conductivity. The second electrode 12 is made of, for example, a metal such as Cu, Al, or Au. Ta or Ti may be laminated above and below these metals. A laminated film of Cu and Ta, a laminated film of Ta, Cu and Ti, or a laminated film of Ta, Cu and TaN may also be used. TiN or TaN may also be used as the second electrode 12. The film thickness of the second electrode 12 is, for example, 200 nm to 800 nm.

The second electrode 12 may be transparent to the light irradiated to the magnetic element 10. Similarly to the first electrode 11, the second electrode 12 may be made of a transparent electrode material such as an oxide, for example, indium tin oxide (ITO), indium zinc oxide (IZO), zinc oxide (ZnO), or indium gallium zinc oxide (IGZO). Even when light is irradiated from the first electrode 11, the light may reach the second electrode 12 depending on the intensity of the light. In this case, since the second electrode 12 is made of an oxide transparent electrode material, the reflection of light at the interface between the second electrode 12 and the layer in contact therewith can be suppressed compared to when the second electrode 12 is made of a metal.

As shown in FIG. 1, the light detection element 101 has a lens 20, i.e., a first lens 20₁ and a second lens 20₂, provided on an insulating layer 16. The first lens 20₁ and the second lens 20₂ are rectangular in plan view from the z-axis direction, but may be circular, polygonal, or the like.

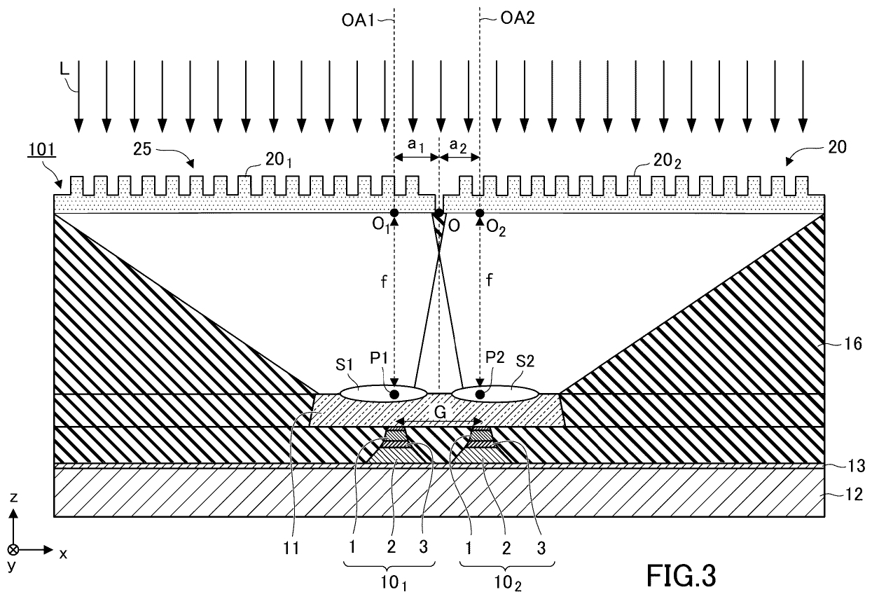

FIG. 3 is a diagram showing how the light L incident on the light detection element 101 is focused by the lens 20 and irradiated to the magnetic element 10 in the light detection element 101 shown in FIG. 1. Specifically, the light focused by the first lens 20₁ is irradiated to the first magnetic element 10₁. The light focused by the second lens 20₂ is irradiated to the second magnetic element 10₂.

FIG. 3 is a diagram showing how the light L incident on the light detection element 101 is focused by the lens 20 and irradiated to the magnetic element 10 in the light detection element 101 shown in FIG. 1.

More specifically, the light L incident on the first lens 20₁ is focused by the first lens 20₁ to form a light spot (also called the “light spot before synthesis”) centered on a focal point P1 at a focal length f. The light L incident on the second lens 20₂ is focused by the second lens 20₂ to form a light spot (also called the “light spot before synthesis”) centered on a focal point P2 at a focal length f. The focal point P1 of the first lens 20₁ and the focal point P2 of the second lens 20₂ are close to each other but separated by a distance G, and the light spot before synthesis at the focal length f of the first lens 20₁ and the light spot before synthesis at the focal length f of the second lens 20₂ partially overlap each other, causing optical interference. The distance G is, for example, 1 μm, and the focal length f is, for example, 100 μm.

The focal point P1 of the first lens 20₁ and the focal point P2 of the second lens 20₂ are at different points on the same plane, and the phase at the focal point P1 of the first lens 20₁ and the phase at the focal point P2 of the second lens 20₂ are different from each other. This makes it possible to suppress the strengthening of light intensity due to light interference in the area where the light irradiated from the first lens 20₁ to the first magnetic element 10₁ and the light irradiated from the second lens 20₂ to the second magnetic element 10₂ overlap. As a result, when the light passing through the first lens 20₁ and the light passing through the second lens 20₂ are combined, the light spot S1 formed by the first lens 20₁ and the light spot S2 formed by the second lens 20₂ are separated, and strong light can be irradiated to each of the first magnetic element 10₁ and the second magnetic element 10₂. This makes it possible to improve the S/N ratio in the light detection of the light detection element 101.

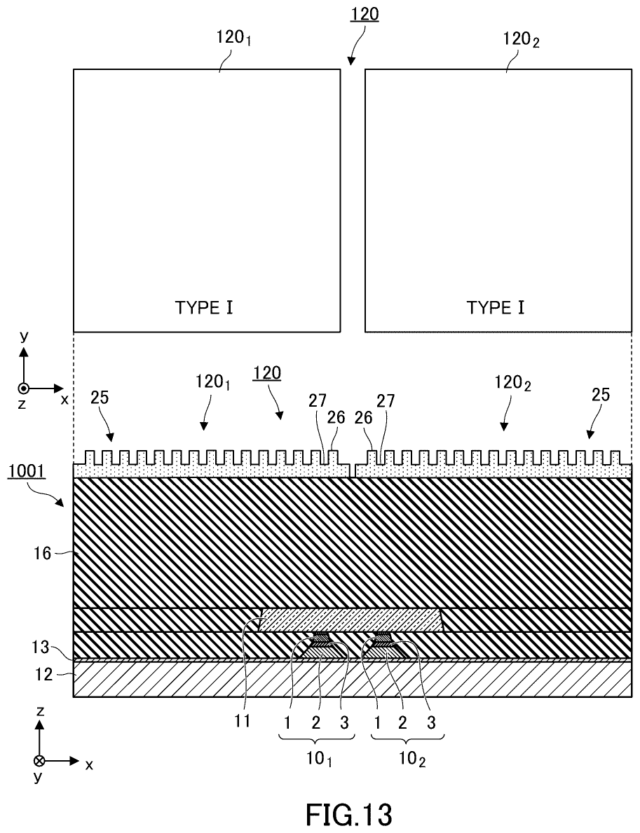

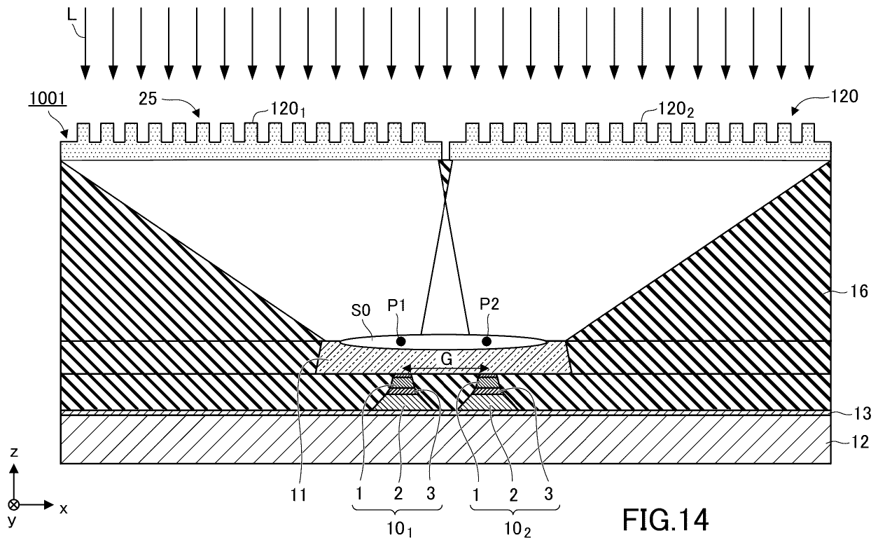

In contrast, in the light detection element 1001 of the related art, as shown in FIGS. 13 and 14, the light spot formed by the first lens 120₁ and the light spot formed by the second lens 120₂ partially overlap in phase. The overlapping parts of the light interfere with each other, strengthening the light intensity, and forming a relatively large light spot S0. The light spot formed by the first lens 120₁ and the light spot formed by the second lens 120₂ cannot be separated. Therefore, compared to the first embodiment of the present disclosure, it is not possible to efficiently irradiate the first magnetic element 10₁ and the second magnetic element 10₂ with strong light.

Returning to FIG. 3, in the first embodiment of the present disclosure, the focal point P1 of the first lens 20₁ is arranged to overlap the first magnetic element 10₁ when viewed from the z-axis direction (direction perpendicular to the surface). This makes it possible to irradiate the first magnetic element 10₁ with strong light. Here, the “direction perpendicular to the surface” refers to the direction perpendicular to the main surface of the lens, or the direction of the optical axis OA1.

The focal point P2 of the second lens 20₂ is arranged so as not to overlap with the first magnetic element 10₁ when viewed from the z-axis direction (the direction perpendicular to the surface or the direction of the optical axis OA2). This reduces the effect of light being cancelled out in the first magnetic element 10₁, and allows strong light to be irradiated onto the first magnetic element 10₁.

The focal point P2 of the second lens 20₂ may be arranged in a light spot (before synthesis) formed on a plane (focal plane) on which the focal point P1 of the first lens 20₁ exists. This allows the distance G between the focal point P1 of the first lens 20₁ and the focal point P2 of the second lens 20₂ to be shortened. This allows the distance between the first magnetic element 10₁ and the second magnetic element 10₂ to be shortened, allowing the magnetic elements 10 to be arranged at a high density.

The first lens 20₁ and the second lens 20₂ may be arranged on the same plane. This allows the manufacturing process to be simplified.

The phase at the focal point P1 of the first lens 20₁ and the phase at the focal point P2 of the second lens 20₂ may be different by 180 degrees. This makes it possible to suppress the enhancement of light intensity due to the interference of light collected from each lens, or to enhance the cancellation effect due to the interference of light.

At least one of the first lens 20₁ and the second lens 20₂ may be a metalens 25 having a plurality of nanostructures 26 arranged two-dimensionally. This allows them to be integrally molded in the same process as the magnetic element 10, making the manufacturing process easier. In this embodiment, the first lens 20₁ and the second lens 20₂ are metalenses 25 each having a plurality of nanostructures 26 arranged two-dimensionally.

The metalens 25 is a lens that applies a metasurface. The metalens 25 functions as a lens by controlling the phase distribution of light. The metasurface exerts the function of a metamaterial by using a planar structure. A metamaterial is a medium that has a negative refractive index, or is designed to have a refractive index (dielectric constant, magnetic permeability) that does not exist in nature. The metalens 25 can reduce the focal length, thereby making it possible to miniaturize the light detection element 101.

The metalens 25 includes, for example, a dielectric material in which surface plasmon excitation occurs. The metalens 25 transmits light in the band of use. The metalens 25 may be made of at least one material selected from the group consisting of, for example, tantalum oxide, silicon nitride, titanium oxide, gallium oxide, silicon oxide, and aluminum oxide. The film thickness of the metalens 25, i.e., the thickness in the z-axis direction, is, for example, 100 nm to 10 μm.

The metalens 25 can control the phase distribution of light by adjusting the arrangement of the multiple nanostructures 26, the size of each nanostructure 26, and the arrangement period of the multiple nanostructures 26. In addition, by adjusting the size and arrangement period of the nanostructures 26, the focal length of the metalens 25 can be made the same even if the wavelength of the incident light is different.

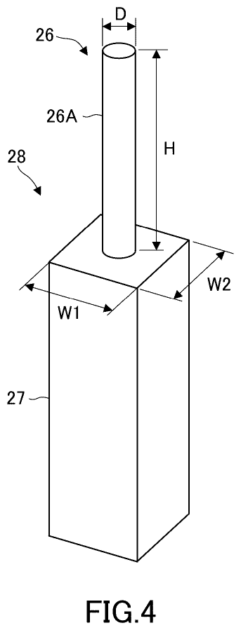

FIG. 4 is a perspective view showing the configuration of the unit structures 28 that make up the metalens 25. As shown in FIG. 4, the unit structure 28 constituting the metalens 25 includes a base portion 27 and a pillar 26A as a nanostructure 26. The base portion 27 is a rectangular parallelepiped, and its upper surface is a rectangle with a width W1 and a depth W2. The width W1 is, for example, 450 nm, and the depth W2 is, for example, 450 nm. The pillar 26A is formed on the upper surface of the base portion 27, and is a cylinder with a diameter D and a height H. The diameter D of the pillar 26A is, for example, 40 to 360 nm, and the height His, for example, 2 μm. The base portion 27 and the pillar 26A are made of, for example, SiO₂.

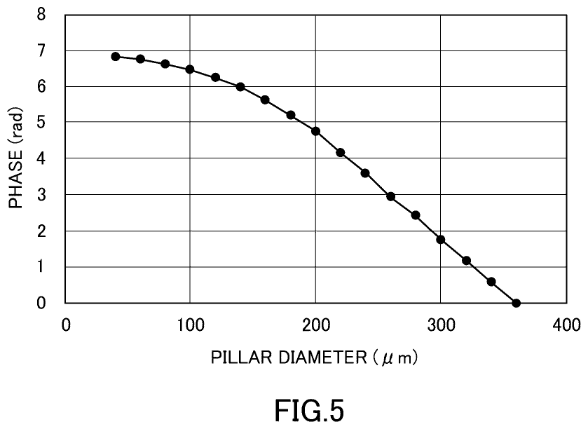

FIG. 5 is a graph showing the results of a simulation of the relationship between the diameter D of the pillar 26A and the phase of the light passing through the pillar 26A. The wavelength of the incident light was set to 520 nm. As shown in FIG. 5, the diameter D of the pillar 26A and the phase of the light correspond one-to-one, and as the diameter D of the pillar 26A increases, the phase of the light decreases. Therefore, by changing the diameter D of the pillar 26A, the phase of the light passing through the pillar 26A can be changed.

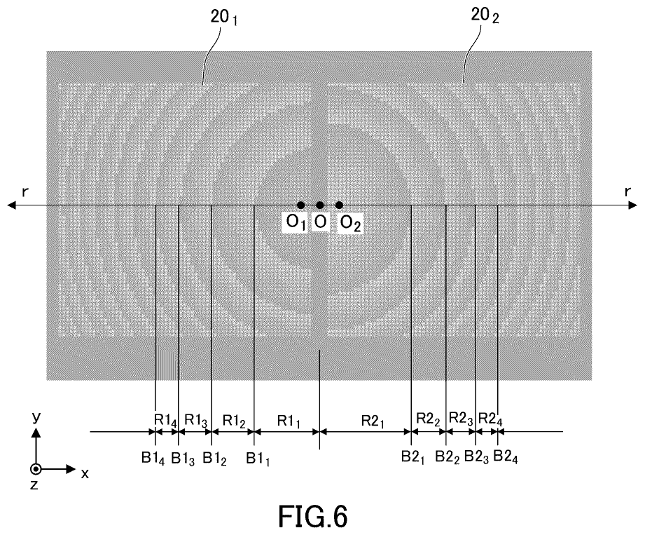

FIG. 6 is a plan view showing the results of a simulation of the configuration of the metalens 25 in FIG. 1. As shown in FIG. 6, the metalens 25 has a plurality of nanostructures 26 arranged two-dimensionally on the xy plane. The plurality of nanostructures 26 may be arranged in a predetermined arrangement pattern within a region R on the base portion 27, such as a semicircular, circular, annular, partial annular, etc. shape. The nanostructure 26 in FIG. 6 is a cylindrical pillar 26A, but may be a square pillar, a rectangular parallelepiped, etc.

When the nanostructure 26 is a cylindrical pillar 26A, the metalens 25 may include a plurality of types of nanostructures 26 with different diameters D of the circular upper surface and different cylindrical heights H. When the nanostructure 26 is a rectangular parallelepiped, the metalens 25 may change the arrangement angle of the nanostructure 26 depending on the position within the region R. The arrangement angle is the angle that the longitudinal direction of the rectangular upper surface of the nanostructure 26 makes with respect to a reference axis (e.g., the x-axis direction). The distribution of the arrangement angles may have, for example, the regularity of the Pancharatnam Berry geometric topology. The size of the upper surface of the nanostructure 26 (diameter D of the circular upper surface in the case of a cylinder, the longitudinal length of the upper surface rectangle in the case of a rectangular parallelepiped, and the width in the short direction) and the interval between adjacent nanostructures 26 are equal to or less than the wavelength of the light used.

The area of each of the multiple nanostructures 26 contained in the region R, such as a semicircular, circular, annular, or partial annular shape, as viewed in a planar view from the z-axis direction may be changed, for example, depending on the distance from the center of the region R. The area of each of the multiple nanostructures 26 contained in the region R, as viewed in a planar view from the z-axis direction, may be made smaller, for example, as it moves from the center of the region R to the outside. The center of region R is the center of a circle or annulus, and in the case of a semicircle or partial annulus, it is the center of a complete circle or annulus that partially includes them.

More specifically, as shown in FIG. 6, the size (or diameter or area) of the multiple nanostructures 26 in the first lens 20₁ in plan view as viewed from the z-axis direction (optical axis direction) decreases as the distance from the optical center O₁ of the first lens 20₁ increases in each region defined by the discontinuity points in the following equation (1) as boundaries.

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

The size (or diameter or area) of the multiple nanostructures 26 in the second lens 20₂ in plan view as viewed from the z-axis direction (optical axis direction) decreases as the distance from the optical center O₂ of the second lens 20₂ increases in each region defined by the discontinuity points in the following equation (2) as boundaries.

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

In the above equations (1) and (2), r is the distance from the origin O, f is the focal length of the first lens 20₁ and the second lens 20₂, λ is the wavelength of the incident light, φ is the phase of the light, a₁ is the distance from the origin O to the optical center O₁ of the first lens 20₁, a₂ is the distance from the origin O to the optical center O₂ of the second lens 20₂, Δφ is the phase difference, and floor is a floor function that returns the largest integer less than or equal to the argument. The optical center O₁ of the first lens 20₁ is the principal point of the first lens 20₁ and is the intersection of the optical axis passing through the focal point P1 of the first lens 20₁ and the principal surface of the first lens 20₁. The optical center O₂ of the second lens 20₂ is the principal point of the second lens 20₂ and is the intersection of the optical axis passing through the focal point P2 of the second lens 20₂ and the principal surface of the second lens 20₂. The phase difference Δφ is, for example, π [rad].

The phase φ(r) in equation (1) decreases monotonically from 0 to −2π, and when it reaches −2π, it repeats the behavior of returning to 0. That is, φ(r) becomes a discontinuous point at r=B1₁, B1₂, B1₃, B1₄, . . . where φ(r)=−2π. In the first lens 20₁, the discontinuous points B1₁, B1₂, B1₃, B1₄, . . . are used as boundaries to define regions R11, R12, R13, R14, . . . between adjacent discontinuous points. However, the region R11 is a region within a circle centered on the optical center O₁ and passing through the discontinuous point B1₁. Considering the relationship between the phase and the pillar diameter in FIG. 5, the pillar diameter at any position in each region can be determined.

In other words, the planar size (or diameter or area) of the multiple nanostructures 26 (pillars 26A) in the first lens 20₁ as viewed from the z-axis direction becomes smaller as the distance from the optical center O₁ of the first lens 20₁ increases in each of the regions R1₁, R1₂, R1₃, R1₄, . . . defined by the discontinuity points B1₁, B1₂, B1₃, B1₄, . . . of equation (1) as boundaries. A lens in which multiple nanostructures 26 are patterned based on equation (1) in this way is also called a “Type I” lens.

The phase φ(r) in equation (2) monotonically decreases from Δφ to Δφ−2π, and repeats the behavior of returning to Δφ when it reaches Δφ−2π. That is, in the second lens 20₂, regions R2₁, R2₂, R2₃, R2₄, . . . are defined between adjacent discontinuities with the discontinuities B2₁, B2₂, B2₃, B2₄, . . . as boundaries. However, region R2₁ is a region within a circle centered on the optical center O₂ and passing through the discontinuity B2₁.

That is, the size (or diameter or area) of the multiple nanostructures 26 (pillars 26A) in the second lens 20₂ in plan view from the z-axis direction becomes smaller as the distance from the optical center O₂ of the second lens 20₂ increases in each region R2₁, R2₂, R2₃, R2₄, . . . defined with the discontinuities B2₁, B2₂, B2₃, B2₄, . . . of equation (2) as boundaries. A lens in which multiple nanostructures 26 are patterned based on equation (2) in this way is also called a “type II” lens.

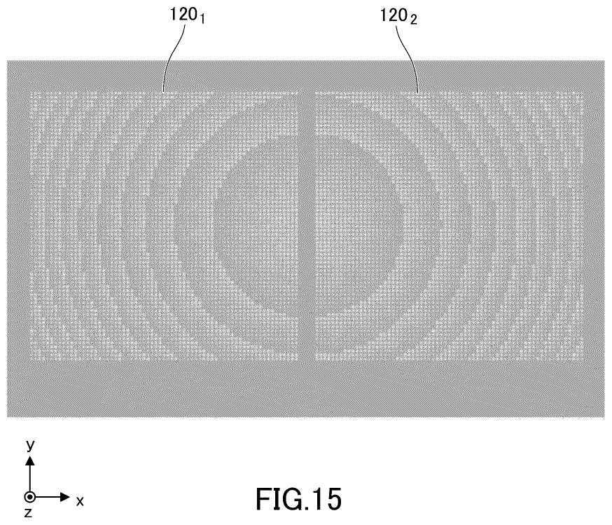

In contrast, in the light detection element 1001 of the related art, as shown in FIG. 15, the configuration of the multiple nanostructures 26 in the second lens 120₂ is a left-right inversion of the configuration of the multiple nanostructures 26 in the first lens 120₁. In this configuration, the phase at the focal point P1 of the first lens 120₁ and the phase at the focal point P2 of the second lens 120₂ are in the same phase, and the light is strengthened by interference. Therefore, the light spot S0 of the synthesized light is larger than that of the first embodiment of the present disclosure.

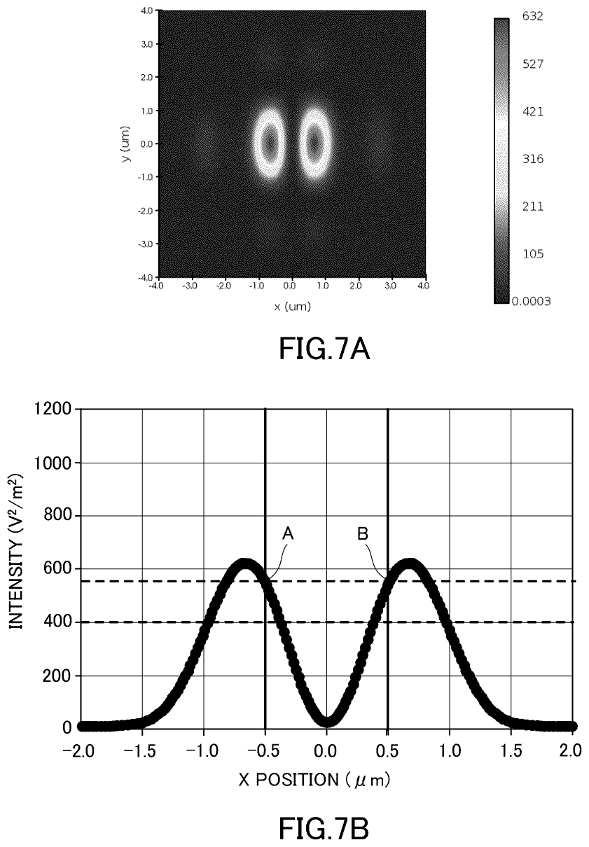

FIG. 7A is a plan view showing the simulation result of the light spot (intensity distribution) on the focal plane in the first embodiment of the present disclosure, and FIG. 7B is a graph showing the simulation result. The first magnetic element 10₁ is provided at a position of x=−0.5 μm, and the second magnetic element 10₂ is provided at a position of x=+0.5 μm. The phase at the focal point P1 of the first lens 20₁ and the phase at the focal point P2 of the second lens 20₂ are different by 180 degrees. As can be seen from FIG. 7A, separate light spots are formed for the first magnetic element 10₁ and the second magnetic element 10₂. Also, from the light intensities at points A and B in FIG. 7B, the intensity (|E|²) of the light irradiated to each magnetic element is 558 [V²/m²].

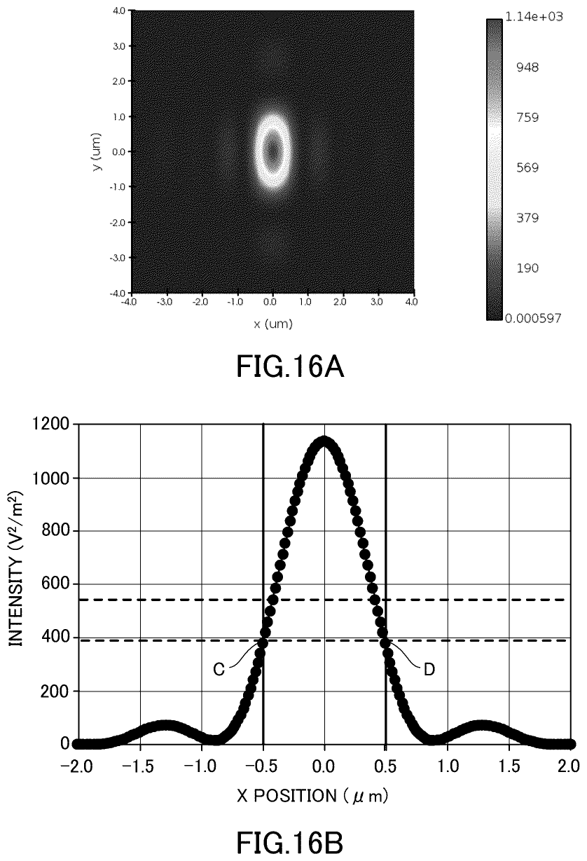

In contrast, in the light detection element 1001 of the related art, as shown in FIG. 16A, one light spot is formed for the first magnetic element 10₁ and the second magnetic element 10₂. Also, from the light intensities at points C and D in FIG. 16B, the intensity (|E|2) of the light irradiated to the first magnetic element 10₁ and the second magnetic element 10₂ is 345 [V²/m²], which is lower than that of the first embodiment of the present disclosure shown in FIGS. 7A and 7B.

As described above, in the light detection element 1001 according to the related art, the phases at the focal points P1 and P2 of the adjacent lenses 120₁ and 120₂ are the same, and the light spots cannot be separated for each magnetic element 10. In other words, the light spots collected from the two lenses 120₁ and 120₂ are combined to become a single light spot S0. In contrast, in the first embodiment of the present disclosure, the phases at the focal points P1 and P2 of the adjacent lenses 20₁ and 20₂ are different, so that the light spots S1 and S2 can be separated for each magnetic element 10₁ and 10₂.

In the first embodiment, the light incident on the lens 20 may be light that has passed through a polarizing filter. The light detection element 101 may have a polarizing filter on the side of the lens 20 opposite to the magnetic element 10. If the light incident on the light detection element 101 is polarized light such as laser light, the polarizing filter may not be necessary.

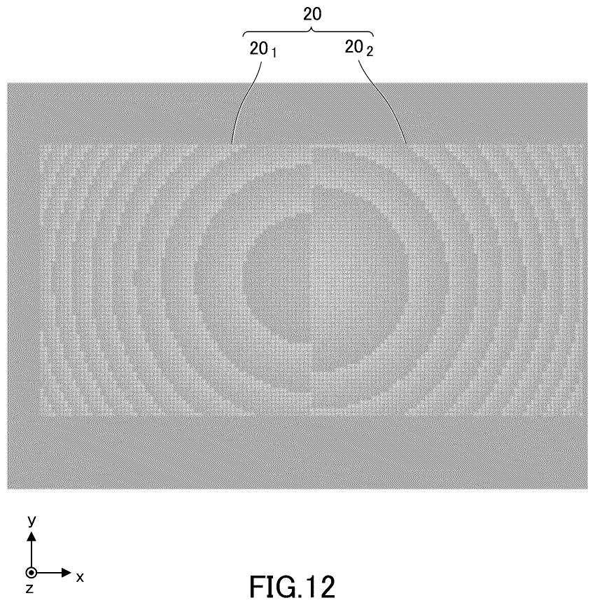

FIG. 12 is a plan view showing the simulation results of a modification of the metalens 25 in FIG. 1. In the modification shown in FIG. 12, the first lens 20₁ and the second lens 20₂ are formed in different regions of one lens 20. Specifically, the first lens 20₁ and the second lens 20₂ are formed integrally, and the multiple nanostructures 26 of the first lens 20₁ are arranged in the region to the left of the center, and the multiple nanostructures 26 of the second lens 20₂ are arranged in the region to the right of the center. This makes it easier to form the first lens 20₁ and the second lens 20₂ as a single unit, rather than forming the lenses individually.

The light-detecting element 101 is obtained by sequentially fabricating the second electrode 12, the magnetic element 10, the first electrode 11, the insulating layer 16, and the lens 20.

The magnetic element 10 (the first magnetic element 10₁ and the second magnetic element 10₂) is fabricated by a lamination process, an annealing process, a processing process, and the like for each layer. First, the cap layer 13, the second ferromagnetic layer 2, the spacer layer 3, the first ferromagnetic layer 1, and the cap layer 4 are laminated on the second electrode 12 in this order. Each layer is formed by, for example, sputtering.

The laminated film is then annealed. The annealing temperature is, for example, 250° C. to 400° C. Thereafter, the laminated film is processed into a columnar laminate 15 by, for example, photolithography and etching. In this embodiment, two laminates 15 are formed. The laminate 15 may be, as a whole or each layer, mesa-shaped, cylindrical, prismatic, truncated cone-shaped, truncated pyramid-shaped, etc. The shortest width of the laminate 15 when viewed from the z-axis direction is, for example, 10 nm to 1000 nm.

Next, an insulating layer 16 is formed so as to cover the side surface of the laminate 15. The insulating layer 16 may be laminated multiple times. Next, the upper surface of the cap layer 4 is exposed from the insulating layer 16 by, for example, chemical mechanical polishing, and a first electrode layer is formed on the cap layer 4 and the insulating layer 16 by sputtering. The first electrode layer is processed into a columnar or plate-shaped first electrode 11, for example, cylindrical, prismatic, truncated cone, truncated pyramid, etc. by, for example, photolithography and etching. Next, the insulating layer 16 is embedded around the first electrode 11. Next, if necessary, the upper surface of the first electrode 11 is exposed from the insulating layer 16 by, for example, chemical mechanical polishing. Next, the insulating layer 16 is formed on the first electrode 11 and the insulating layer 16. The insulating layer 16 may be laminated multiple times.

Next, the lens 20 (first lens 20₁ and second lens 20₂) is provided on the insulating layer 16. Specifically, the base portion 27 is formed on the upper surface of the insulating layer 16, a resist having a predetermined pattern formed thereon by photolithography is formed on the upper surface of the base portion 27, and dry etching is performed. A metalens 25 is formed by forming a plurality of nanostructures 26 of a predetermined pattern on the upper surface of the base portion 27 by dry etching. The light detection element 101 is obtained by the above process. In this way, in the production of the light detection element 101, the magnetic element 10 to the metalens 25 can be formed continuously by a vacuum film formation process.

In addition, the first lens 20₁ and the second lens 20₂ are metalenses, but may be, for example, microlenses. If the lens 20 is a metalenses, the first lens 20₁ and the second lens 20₂ can be integrally molded in the same process as the magnetic element 10, making the manufacturing process easier.

Next, the operation of the light detection element 101 according to the first embodiment will be explained.

As shown in FIG. 3, the incident light L on the light detection element 101 is focused by the lens 20 and irradiated to the magnetic element 10, particularly the first ferromagnetic layer 1. When the intensity of the light irradiated to the first ferromagnetic layer 1 changes, the state of the magnetization M1 of the first ferromagnetic layer 1 changes. The state of the magnetization M1 is, for example, the inclination angle of the magnetization M1 with respect to the z-axis direction, the magnitude of the magnetization M1, etc.

For example, when the intensity of the light irradiated to the first ferromagnetic layer 1 increases, the magnetization M1 of the first ferromagnetic layer 1 tilts from its initial state due to the external energy caused by the light irradiation. The angle between the direction of the magnetization M1 of the first ferromagnetic layer 1 when the first ferromagnetic layer 1 is not irradiated with light and the direction of the magnetization M1 when the first ferromagnetic layer 1 is irradiated with light is, for example, greater than 0° and smaller than 90°. Alternatively, for example, when the intensity of the light irradiated to the first ferromagnetic layer 1 increases, the magnitude of the magnetization M1 decreases.

When the state of the magnetization M1 of the first ferromagnetic layer 1 changes, the resistance value of the magnetic element 10 in the z-axis direction changes due to the magnetoresistance effect. When a constant current (sense current) is passed through the magnetic element 10 in the positive or negative z-axis direction using the first electrode 11 and the second electrode 12, an output voltage is obtained from the magnetic element 10. That is, when the state of the magnetization M1 of the first ferromagnetic layer 1 changes, the output voltage from the magnetic element 10 also changes.

The intensity of the light irradiated to the first ferromagnetic layer 1 may take two values, for example, a first intensity and a second intensity. The first intensity may be the case when the intensity of the light irradiated to the first ferromagnetic layer 1 is zero. The intensity of the light irradiated to the first ferromagnetic layer 1 may take multiple values, or may change in an analog manner. When the intensity of the incident light takes multiple values, the output voltage of the magnetic element 10 can also take multiple values, and when the intensity of the light changes in an analog manner, the output voltage of the magnetic element 10 can also change in an analog manner. The difference between these output voltages (resistance values) can be read out from the light detection element 101 as binary, multi-value, or analog data.

In a state where the first ferromagnetic layer 1 is irradiated with light of a first intensity (referred to as the “initial state”), the magnetization M1 of the first ferromagnetic layer 1 and the magnetization M2 of the second ferromagnetic layer 2 may be parallel or anti-parallel, or may be perpendicular to each other.

When the magnetizations M1 and M2 are parallel in the initial state, a sense current is passed from the first ferromagnetic layer 1 to the second ferromagnetic layer 2. By passing the sense current in this direction, a spin transfer torque in the same direction as the magnetization M2 of the second ferromagnetic layer 2 acts on the magnetization M1 of the first ferromagnetic layer 1, and the magnetizations M1 and M2 become parallel in the initial state. Also, by passing the sense current in this direction, it is possible to prevent the magnetization M1 of the first ferromagnetic layer 1 from reversing during operation.

When the magnetization M1 and magnetization M2 are antiparallel in the initial state, it is preferable to flow the sense current from the second ferromagnetic layer 2 to the first ferromagnetic layer 1. By flowing the sense current in this direction, a spin transfer torque in the opposite direction to the magnetization M2 of the second ferromagnetic layer 2 acts on the magnetization M1 of the first ferromagnetic layer 1, and the magnetization M1 and magnetization M2 become antiparallel in the initial state.

When the intensity of the light irradiated to the first ferromagnetic layer 1 returns to the first intensity, a spin transfer torque acts due to the sense current, or the state of the magnetization M1 of the first ferromagnetic layer 1 returns to its original state due to the effect of magnetic anisotropy, and the magnetic element 10 returns to its initial state.

In this way, the light detection element 101 according to the first embodiment can convert a change in the intensity of the irradiated light into a change in the output voltage from the magnetic element 10. In other words, the light detection element 101 can convert light into an electrical signal.

As described above, in the first embodiment of the present disclosure, in order to improve the sensitivity of the magnetic element 10, multiple magnetic elements 10 (first magnetic element 10₁ and second magnetic element 10₂) are arranged, and multiple lenses 20 are arranged to irradiate light onto each of the multiple magnetic elements 10. Then, in the portion where light passing through, for example, adjacent lenses 20 (first lens 20₁ and second lens 20₂) among the multiple lenses 20 overlaps, the strengthening of light intensity due to light interference is suppressed, or the light intensity is weakened by light interference, or the light is cancelled out by light interference. For this purpose, the phases at the respective focal points of the adjacent lenses 20 are made to differ from each other by, for example, 180 degrees. This allows the light spots created by the adjacent lenses 20 to be separated, and strong light to be irradiated onto each of the multiple magnetic elements 10, thereby improving the S/N ratio in the light detection of the light detection element 101.

Next, a second embodiment of the present disclosure will be described.

The second embodiment differs from the first embodiment in that the second embodiment has three or more magnetic elements and three or more lenses. The other configurations are the same as those of the first embodiment, and the same components are given the same reference numerals and descriptions are omitted as appropriate.

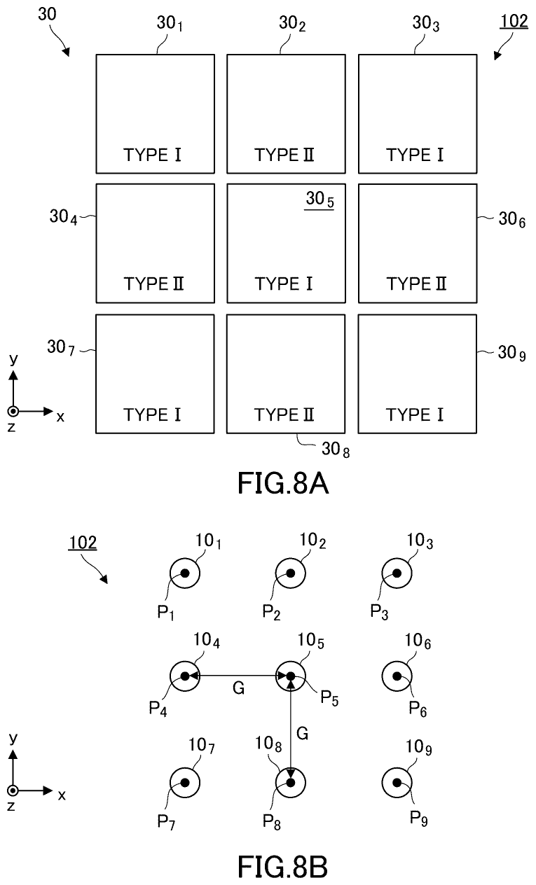

FIG. 8A is a plan view showing the configuration of the lens 30 of the light detection element 102 according to the second embodiment, and FIG. 8B is a plan view showing the configuration of the magnetic element 10. As shown in FIGS. 8A and 8B, the light detection element 102 has nine magnetic elements 10₁, 10₂, 10₃, 10₄, 10₅, 10₆, 10₇, 10₈, and 10₉ and nine lenses 30₁, 30₂, 30₃, 30₄, 30₅, 30₆, 30₇, 30₈, and 30₉. The number of magnetic elements 10 and the number of lenses 10 are each 9, but are not limited to this and may be any integer of 3 or more.

As shown in FIG. 3, each of the magnetic elements 10₁, 10₂, 10₃, 10₄, 10₅, 10₆, 10₇, 10₈, and 10₉ includes a first ferromagnetic layer 1, a second ferromagnetic layer 2, and a spacer layer 3 sandwiched between the first ferromagnetic layer 1 and the second ferromagnetic layer 2. Each lens 30 irradiates light to the corresponding magnetic element 10. Specifically, the lenses 30₁, 30₂, 30₃, 30₄, 30₅, 30₆, 30₇, 30₈, and 30₉ irradiate light to the magnetic elements 10₁, 10₂, 10₃, 10₄, 10₅, 10₆, 10₇, 10₈, and 10₉, respectively. Each lens 10 is rectangular, but may be any shape such as circular or polygonal.

The magnetic elements 10₁, 10₂, 10₃, 10₄, 10₅, 10₆, 10₇, 10₈, and 10₉ are arranged, for example, in a lattice pattern, but the arrangement pattern is not limited to this and can be selected arbitrarily. The distance G between adjacent magnetic elements 10 is, for example, 1 μm. By arranging multiple magnetic elements 10 in a lattice pattern, the integration degree of the magnetic elements 10 can be increased.

The lenses 30₁, 30₂, 30₃, 30₄, 30₅, 30₆, 30₇, 30₈, and 30₉ are also arranged in a lattice pattern, but the arrangement pattern may be changed depending on the arrangement pattern of the magnetic elements 10. By arranging multiple lenses 30 in a lattice pattern, the integration degree of the lenses 30 can be increased.

The focal point Pn of at least one lens 30ₙ of the multiple lenses 30 is arranged so as to overlap the magnetic element 10ₙ corresponding to that lens 30ₙ when viewed from the z-axis direction (direction perpendicular to the surface) (n is an integer between 1 and 9). This allows strong light to be irradiated onto the magnetic element 10ₙ.

In this embodiment, as shown in FIG. 8B, when viewed from the z-axis direction, focal point P₁ of lens 30₁ overlaps with magnetic element 10₁, focal point P₂ of lens 30₂ overlaps with magnetic element 10₂, focal point P₃ of lens 30₃ overlaps with magnetic element 10₃, focal point P₄ of lens 30₄ overlaps with magnetic element 10₄, focal point P₅ of lens 30₅ overlaps with magnetic element 10₅, focal point P₆ of lens 30₆ overlaps with magnetic element 10₆, focal point P₇ of lens 30₇ overlaps with magnetic element 10₇, focal point P₈ of lens 30₈ overlaps with magnetic element 10₈, and focal point P₉ of lens 30₉ overlaps with magnetic element 10₉.

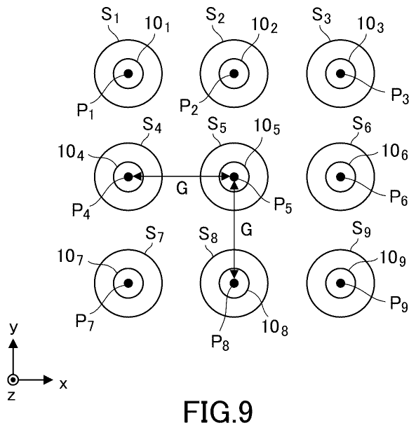

FIG. 9 is a plan view showing the configuration of the light spot formed by lens 30 of light detection element 10₂ in FIGS. 8A and 8B. As shown in FIG. 9, on a focal plane perpendicular to the z-axis direction, lens 30₁ forms a light spot S₁ centered on focal point P₁. Lens 30₂ forms a light spot S₂ centered on focal point P₂. Lens 30₃ forms a light spot S₃ centered on focal point P₃. Lens 30₄ forms a light spot S₄ centered on focal point P₄. Lens 30₅ forms a light spot S₅ centered on focal point P₅. Lens 30₆ forms a light spot S₆ centered on focal point P₆. Lens 30₇ forms a light spot S₇ centered on focal point P₇. Lens 30₈ forms a light spot S₈ centered on focal point P₈. Lens 30₉ forms a light spot S₉ centered on focal point P₉. Light spots S₁ to S₉ do not overlap with adjacent light spots.

As described above, the focal points of the multiple lenses 30 are at different points on the same plane. The phases at the focal points of the multiple lenses 30 are different from the phases at the focal points of the adjacent lenses. This makes it possible to suppress the strengthening of light intensity caused by the interference of light irradiated from the lenses 30 to the magnetic elements 10. It is possible to efficiently irradiate each of the magnetic elements 10 with strong light. This improves the S/N ratio in the light detection of the light detection element 102.

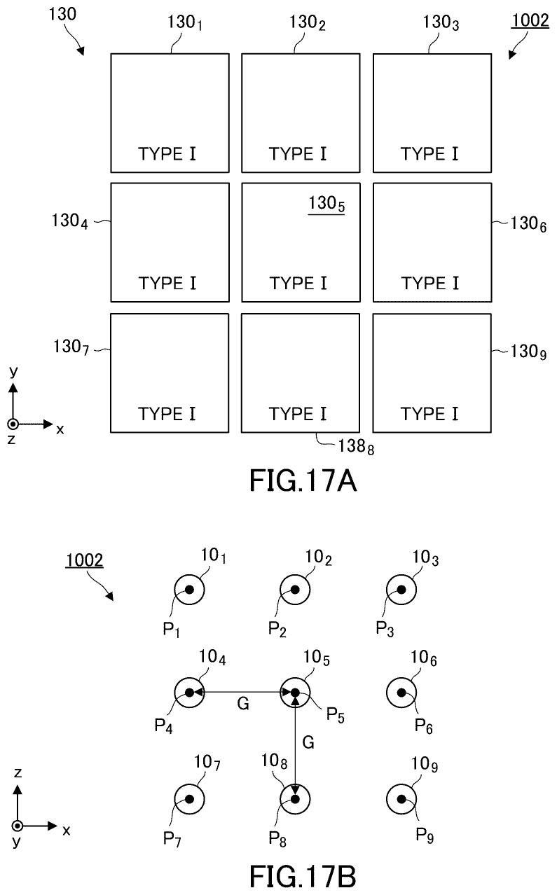

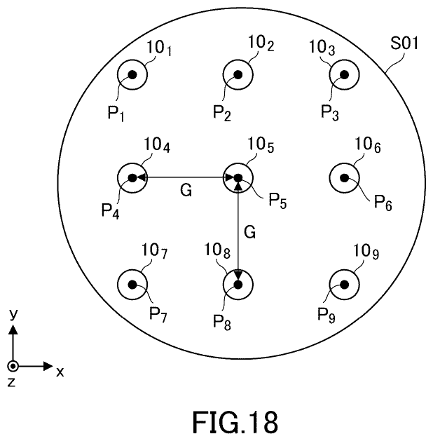

In contrast, in the light detection element 1002 of the related art, as shown in FIGS. 17 and 18, the phases at the focal points of the lenses 1301, 1302, 1303, 1304, 1305, 1306, 1307, 1308, and 1309 are the same as the phases at the focal points of the adjacent lenses 130. This causes the strengthening of light intensity caused by the interference of light irradiated from the lenses 130 to the magnetic elements 10, forming a large light spot S01 overall. It is not possible to separate the light spot formed by each lens 130 from the light spot formed by its adjacent lens 130. Therefore, in the light detection element 1002, compared to the second embodiment of the present disclosure, it is not possible to efficiently irradiate each of the multiple magnetic elements 10 with strong light.

In the second embodiment of the present disclosure, the focal point Pn of at least one lens 30ₙ of the multiple lenses 30 may be arranged so as not to overlap with the magnetic elements 10 other than the magnetic element 10ₙ that irradiates the light when viewed from the z-axis direction (direction perpendicular to the surface) (n is an integer between 1 and 9). This reduces the effect of light being canceled out in the magnetic elements 10 other than the magnetic element 10ₙ that irradiates the light, and strong light can be irradiated to the magnetic element 10.

The focal point Pₙ of at least one lens 30ₙ of the multiple lenses 30 may be arranged in a light spot formed on a plane on which the focal points of the other adjacent lenses 30 exist (n is an integer between 1 and 9). This makes it possible to shorten the distance G between the respective focal points of two adjacent lenses 30. This makes it possible to shorten the distance between the magnetic elements 10 corresponding to each of the two lenses 30, and therefore to arrange the magnetic elements 10 at a high density.

At least two of the lenses 30 are arranged on the same plane. This can facilitate the manufacturing process.

At least two adjacent lenses 30 of the lenses 30 have phases at their respective focal points that differ by, for example, 180 degrees. This can prevent the reinforcement caused by interference of light collected from adjacent lenses 30.

At least two of the lenses 30 may be formed in different regions of one lens. This can facilitate the manufacturing process of at least these two lenses 30.

At least one of the lenses 30 is a metalens that includes a plurality of nanostructures 26 arranged two-dimensionally. This can be integrally molded in the same process as the magnetic element 10, making the manufacturing process easier. In this embodiment, lenses 30₁, 30₂, 30₃, 30₄, 30₅, 30₆, 30₇, 30₈, and 30₉ are metalenses each having a plurality of nanostructures 26 arranged two-dimensionally.

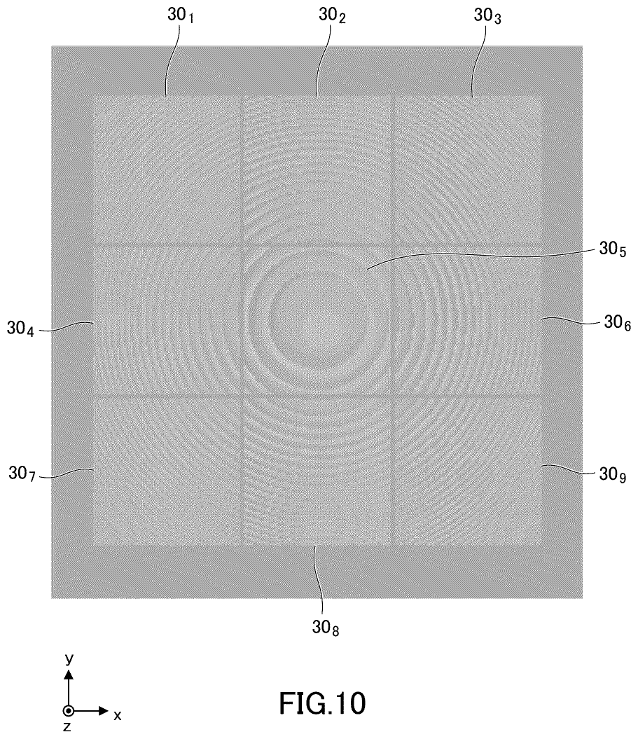

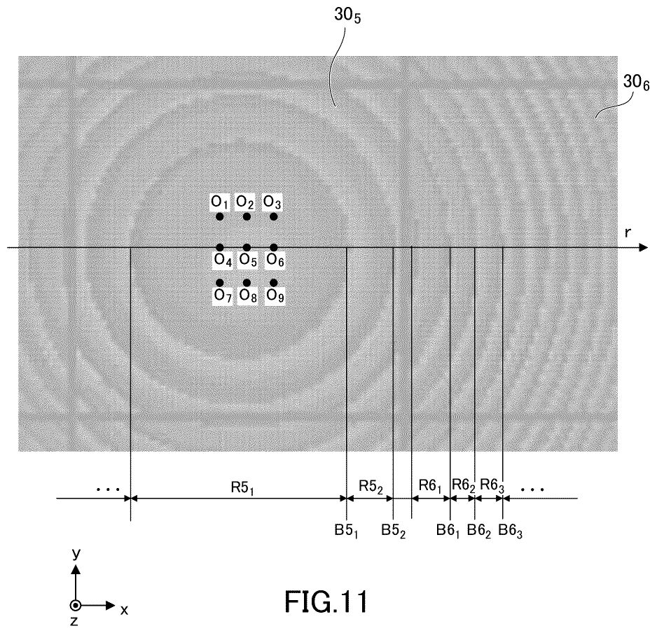

FIG. 10 is a plan view showing the results of a simulation of the configuration of lens 30 consisting of the metalens shown in FIG. 8A, and FIG. 11 is a partially enlarged plan view of FIG. 10.

Lens 30 is classified into a first group and a second group such that adjacent lenses belong to different groups. Specifically, lenses 30₁, 30₂, 30₃, 30₄, 30₅, 30₆, 30₇, 30₈, and 30₉ belong to the first group, and lenses 30₂, 30₄, 30₆, and 30₈ belong to the second group.

As shown in FIG. 11, the planar size (or diameter or area) of the multiple nanostructures 26 in one lens (first group lens) of the adjacent lenses 30 as viewed from the z-axis direction (optical axis direction) decreases as the distance from the optical center of the lens increases in each region defined by the discontinuity points in the following equation (1).

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

The planar size (or diameter or area) of the multiple nanostructures 26 (pillars 26A) in the other lens (second group lens) of the adjacent lenses 30 as viewed from the z-axis direction decreases as the distance from the optical center of the lens increases in each region defined by the discontinuity points in the following equation (2).

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

In the above equations (1) and (2), r is the distance from the origin O, f is the focal length of the lens, λ is the wavelength of the incident light, φ is the phase, a₁ is the distance from the origin O to the optical center of one lens, a₂ is the distance from the origin to the optical center of the other lens, Δφ is the phase difference, and floor is a floor function that returns the largest integer less than or equal to the argument. The optical center Oₙ of the lens 330ₙ On is the principal point of the lens 30ₙ, and is the intersection of the optical axis passing through the focal point Pₙ of the lens 30ₙ and the principal surface of the lens 30ₙ (n is an integer between 1 and 9). The phase difference Δφ is, for example, π [rad].

The phase φ(r) in equation (1) decreases monotonically from 0 to −2π, and when it reaches −2π, it repeats the behavior of returning to 0. That is, φ(r) becomes discontinuous at r=B5₁, B5₂, B5₃, . . . where φ(r)=−2π. In the lens 30₅, regions R5₁, R5₂, . . . are defined between adjacent discontinuities with the discontinuities B5₁, B5₂, . . . as boundaries. However, the region R5₁ is a region within a circle centered on the optical center O₅ and passing through the discontinuity B5₁. The pillar diameter at any position in each region is determined by considering the relationship between the phase and the pillar diameter in FIG. 5.

That is, for example, the size (or diameter or area) of the multiple nanostructures 26 (pillars 26A) in the lens 30₅ in plan view as seen from the z-axis direction becomes smaller as the distance from the optical center O₅ of the lens 30₅ becomes larger in each region R5₁, R5₂, . . . defined with the discontinuities B5₁, B5₂, . . . of the equation (1) as boundaries. The same is true for the other lenses 30₁, 30₃, 30₇, and 30₉ in the first group. A lens in which a plurality of nanostructures 26 are patterned based on equation (1) in this way is also called a “Type I” lens.

The phase φ(r) in equation (2) monotonically decreases from Δφ to Δφ−2π, and when it reaches Δφ−2π, it repeats the behavior of returning to Δφ. That is, for example, for lens 30₆, regions R6₁, R6₂, R6₃, . . . between adjacent discontinuities are determined with discontinuities B6₁, B6₂, B6₃, . . . as boundaries. However, region R6₁ is a region within a circle centered on the optical center O₆ and passing through discontinuity B6₁.

In other words, the planar size (or diameter or area) of the multiple nanostructures 26 (pillars 26A) in lens 30₆ as viewed from the z-axis direction becomes smaller as the distance from the optical center O₆ of lens 30₆ increases in each of regions R6₁, R6₂, R6₃, . . . defined by the discontinuity points B6₁, B6₂, B6₃, . . . of equation (2) as boundaries. The same is true for the other lenses 30₂, 30₄, 30₈ in the second group. A lens in which multiple nanostructures 26 are patterned in this way based on equation (2) is also called a “Type II” lens.

Furthermore, as shown in FIG. 11, the optical centers of lenses 30₁, 30₂, 30₃, 30₄, 30₅, 30₆, 30₇, 30₈, and 30₉ are O₁, O₂, O₃, O₄, O₅, O₆, O₇, O₈, and O₉, respectively, and are provided corresponding to focal points P₁, P₂, P₃, P₄, P₅, P₆, P₇, P₈, and P₉.

The manufacturing process for the light detection element 102 is the same as that of the first embodiment.

As described above, in the second embodiment of the present disclosure, in order to improve the sensitivity of the magnetic element 10, three or more magnetic elements 10 (magnetic elements 10₁ to 10₉) and the same number of lenses 30 (lenses 30₁ to 30₉) are densely arranged, for example, in a lattice pattern. Then, in the portion where the light passing through, for example, adjacent lenses 30 overlap among the multiple lenses 30, the strengthening of the light intensity due to the interference of light is suppressed, or the light intensity is weakened by the interference of light, or the light is cancelled out by the interference of light. For this purpose, the phases at the focal points of the adjacent lenses 30 are made to differ from each other by, for example, 180 degrees. This allows the light spots created by the adjacent lenses 30 to be separated, and strong light to be irradiated onto each of the multiple magnetic elements 10, thereby improving the S/N ratio in the light detection of the light detection element 102.

The light detection elements 101 and 102 of the first and second embodiments can be applied to light sensors such as image sensors in which multiple light detection elements are arranged one-dimensionally or two-dimensionally. Such light sensors can be used in information terminal devices such as smartphones, tablets, personal computers, and digital cameras.

The light detection elements 101 and 102 of the first and second embodiments can be applied to the photoelectric conversion element of a receiver device provided in a transceiver device that transmits and receives optical signals such as laser light in a communication system in which a plurality of transceiver devices are connected by optical fibers. The above communication system may be a communication system that performs short- or medium-distance communication such as within a data center or between data centers, or long-distance communication such as between cities. The transceiver device is installed in a data center, for example.

The above communication system may be a communication system that wirelessly transmits and receives optical signals such as near-infrared light signal between mobile terminals such as smartphones and tablets. The above communication system may be a communication system that wirelessly transmits and receives optical signals such as near-infrared light signal between a mobile terminal and an information processing device such as a personal computer.

The present disclosure is not limited to the above embodiments, and various modifications and changes are possible within the scope of the gist of the present disclosure described in the claims.

As described above, the present disclosure has the effect of suppressing the reinforcement of light intensity due to interference of light passing through adjacent lenses even when multiple lenses are used, and has an excellent S/N ratio in light detection, and is useful for light detection elements in general.

### APPENDIX

One aspect of the present disclosure provides the light detection element that comprises a first magnetic element and a second magnetic element, each of which comprises a first ferromagnetic layer, a second ferromagnetic layer, and a spacer layer sandwiched between the first ferromagnetic layer and the second ferromagnetic layer, a first lens consisting of a metalens having a plurality of nanostructures arranged two-dimensionally, which irradiates incident light to the first magnetic element, and a second lens consisting of a metalens having a plurality of nanostructures arranged two-dimensionally, which irradiates incident light to the second magnetic element, wherein the size of the plurality of nanostructures in the first lens in a planar view seen from the optical axis direction of the first lens decreases as the distance from the optical center of the first lens increases in each region defined by the discontinuity points of equation (1) as boundaries, and the size of the plurality of nanostructures in the second lens in a planar view seen from the optical axis direction of the second lens decreases as the distance from the optical center of the second lens increases in each region defined by the discontinuity points of equation (2) as boundaries.

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

(In the above equations (1) and (2), r is the distance from the origin, f is the focal length of the first lens and the second lens, λ is the wavelength of the incident light, φ is the phase, a₁ is the distance from the origin to the optical center of the first lens, a₂ is the distance from the origin to the optical center of the second lens, Δφ is the phase difference, and floor is the floor function.)

With this configuration, the light detection element of the present disclosure has a different phase at the focal point of the first lens and a different phase at the focal point of the second lens. The focal points of the first lens and the second lens are at different points on the same plane (focal plane). This makes it possible to suppress reinforcement caused by interference of the light irradiated from the first lens and the second lens to the first magnetic element and the magnetic element. This makes it possible to irradiate the first magnetic element and the second magnetic element with strong light, thereby improving the S/N ratio in the light detection of the light detection element. Furthermore, by using metalenses as the first lens and the second lens, the first magnetic element and the second magnetic element can be molded as one piece in the same process, and the manufacturing process can be simplified.

One aspect of the present disclosure provides the light detection element, wherein the focal point of the first lens may be arranged to overlap the first magnetic element when viewed from the optical axis direction of the first lens.

With this configuration, the light detection element of the present disclosure can irradiate the first magnetic element with strong light by being arranged so that the focal point of the first lens overlaps the first magnetic element when viewed from the optical axis direction of the first lens.

One aspect of the present disclosure provides the light detection element, wherein the focal point of the second lens may be arranged so as not to overlap the first magnetic element when viewed from the optical axis direction of the second lens.

With this configuration, the light detection element of the present disclosure can irradiate the first magnetic element with strong light by being arranged so that the focal point of the second lens does not overlap the first magnetic element when viewed from the optical axis direction of the second lens, thereby reducing the effect of light cancellation in the first magnetic element and enabling strong light to be irradiated to the first magnetic element.

One aspect of the present disclosure provides the light detection element, wherein the focal point of the second lens may be located within a light spot formed on a plane where the focal point of the first lens is located and perpendicular to the optical axis direction of the first lens.

With this configuration, the light detection element of the present disclosure can shorten the distance between the focal points of the first lens and the second lens, thereby shortening the distance between the first magnetic element and the second magnetic element, and allowing the magnetic elements to be arranged at a high density.

One aspect of the present disclosure provides the light detection element, wherein the first lens and the second lens may be located on the same plane.

With this configuration, the light detection element of the present disclosure can facilitate the manufacturing process by forming the first lens and the second lens on the same plane.

One aspect of the present disclosure provides the light detection element, wherein the first lens and the second lens may be configured such that the phases at their respective focal points differ by 180 degrees.

With this configuration, the light detection element of the present disclosure can further suppress the reinforcement caused by interference between the light focused from each lens, by having the phases at the focal points of the first lens and the second lens differ by 180 degrees.

One aspect of the present disclosure provides the light detection element, wherein the first lens and the second lens may be formed in different regions of a single lens.

With this configuration, the light detection element of the present disclosure can facilitate the process of forming the first lens and the second lens, by having the first lens and the second lens formed in different regions of a single lens.

One aspect of the present disclosure provides the light detection element that comprises a plurality of magnetic elements, each of which comprises a first ferromagnetic layer, a second ferromagnetic layer, and a spacer layer sandwiched between the first ferromagnetic layer and the second ferromagnetic layer, and a plurality of lenses, each of which irradiates light onto a corresponding magnetic element among the plurality of magnetic elements, and the plurality of lenses are each composed of a metalens having a plurality of nanostructures arranged two-dimensionally. The size of the plurality of nanostructures in one lens of adjacent lenses in a plan view seen from the optical axis direction of the one lens becomes smaller as the distance from the optical center of the one lens increases in each region defined by the discontinuity points of equation (1) as boundaries, and the size of the plurality of nanostructures in the other lens of adjacent lenses in a plan view seen from the optical axis direction of the other lens becomes smaller as the distance from the optical center of the other lens increases in each region defined by the discontinuity points of equation (2) as boundaries.

$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$

$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$

(In the above equations (1) and (2), r is the distance from the origin, f is the focal length of the adjacent lenses, λ is the wavelength of the incident light, φ is the phase, a₁ is the distance from the origin to the optical center of one of the lenses, a₂ is the distance from the origin to the optical center of the other lens, Δφ is the phase difference, and floor is the floor function.)

With this configuration, the light detection element of the present disclosure has a phase difference between the focal point of one adjacent lens and the focal point of the other adjacent lens. The focal points of adjacent lenses are at different points on the same plane (focal plane). This makes it possible to suppress reinforcement caused by interference of light irradiated from the multiple lenses to the multiple magnetic elements. This makes it possible to irradiate each of the multiple magnetic elements with strong light, thereby improving the S/N ratio in the light detection of the light detection element. In addition, since the multiple lenses are metalenses, they can be molded integrally in the same process as the magnetic elements, and the manufacturing process can be made the same.

One aspect of the present disclosure provides the light detection element, wherein the multiple magnetic elements may be arranged in a lattice pattern.

With this configuration, the light detection element of the present disclosure can increase the integration degree of the magnetic elements by arranging the multiple magnetic elements in a lattice pattern.

One aspect of the present disclosure provides the light detection element, wherein the multiple lenses may be arranged in a lattice pattern.

With this configuration, the light detection element of the present disclosure can increase the integration of lenses by arranging the multiple lenses in a lattice pattern.

One aspect of the present disclosure provides the light detection element, wherein the focal point of at least one of the multiple lenses may be arranged to overlap the magnetic element corresponding to the lens when viewed from the optical axis direction of the lens.

With this configuration, the light detection element of the present disclosure can irradiate strong light onto the magnetic element by arranging the focal point of at least one of the multiple lenses to overlap the magnetic element when viewed from the optical axis direction of the lens.

One aspect of the present disclosure provides the light detection element, wherein the focal point of at least one of the multiple lenses may be arranged so as not to overlap with magnetic elements other than the magnetic element irradiated with light by the lens when viewed from the optical axis direction of the lens.

With this configuration, in the light detection element of the present disclosure, the focal point of at least one of the multiple lenses is arranged so as not to overlap with magnetic elements other than the magnetic element to which light is irradiated by the lens when viewed from the optical axis direction, thereby suppressing the effect of light being canceled out in magnetic elements other than the magnetic element irradiating light, and enabling strong light to be irradiated.

One aspect of the present disclosure provides the light detection element, wherein the focal point of at least one of the multiple lenses may be arranged in a light spot formed on a plane where the focal points of other adjacent lenses exist and perpendicular to the optical axis direction of the other lenses.

With this configuration, the light detection element of the present disclosure can shorten the distance between the focal points of each of the two lenses, thereby shortening the distance between the magnetic elements corresponding to each of the two lenses, and allowing the magnetic elements to be arranged at a high density.

One aspect of the present disclosure provides the light detection element, wherein at least two of the multiple lenses may be arranged on the same plane.

With this configuration, at least two of the lenses of the light detection element of the present disclosure are arranged on the same plane, which makes the manufacturing process easier.

One aspect of the present disclosure provides the light detection element, wherein at least two adjacent lenses of the plurality of lenses may be arranged such that the phases at their respective focal points differ by 180 degrees.

With this configuration, at least two adjacent lenses of the light detection element of the present disclosure are arranged such that the phases at their respective focal points differ by 180 degrees, which further reduces the reinforcement caused by the interference of the light focused from each lens.

One aspect of the present disclosure provides the light detection element, wherein at least two of the lenses of the present disclosure may be formed in different regions of a single lens.

With this configuration, at least two of the lenses of the light detection element of the present disclosure are arranged such that the lens forming process is easier.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

1 First ferromagnetic layer
2 Second ferromagnetic layer
3 Spacer layer
4, 13 Cap layer
10, 10₁ to 10₉ Magnetic element
11 First electrode
12 Second electrode
15 Laminate
16 Insulating layer
20, 30, 30₁ to 30₉ Lens
20₁ First lens
20₂ Second lens
25 Metalens
26 Nanostructure
26A Pillar
27 Base portion
28 Unit structure
101, 102 Light detection element
120₁ First lens
120₂ Second lens
1001, 1002 Light detection element
G Distance between the focal points of adjacent lenses
M1, M2 Magnetization
P1, P2, P₁ to P₉ Focal point
S0, S01, S₁ to S₉ Light spot

What is claimed is:

1. A light detection element comprising: a first magnetic element and a second magnetic element, each of which comprises a first ferromagnetic layer, a second ferromagnetic layer, and a spacer layer sandwiched between the first ferromagnetic layer and the second ferromagnetic layer;
a first lens consisting of a metalens having a plurality of nanostructures arranged two-dimensionally, which irradiates incident light to the first magnetic element; and
a second lens consisting of a metalens having a plurality of nanostructures arranged two-dimensionally, which irradiates the incident light to the second magnetic element,
wherein
the size of the plurality of nanostructures in the first lens in a plan view from the optical axis direction of the first lens decreases as the distance from the optical center of the first lens increases in each region defined by the discontinuity points of equation (1) as boundaries, and
the size of the plurality of nanostructures in the second lens in a plan view from the optical axis direction of the second lens decreases as the distance from the optical center of the second lens increases in each region defined by the discontinuity points of equation (2) as boundaries.
$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$
$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$
(In the above equations (1) and (2), r is the distance from the origin, f is the focal length of the first lens and the second lens, λ is the wavelength of the incident light, φ is the phase, a₁ is the distance from the origin to the optical center of the first lens, a₂ is the distance from the origin to the optical center of the second lens, Δφ is the phase difference, and floor is the floor function.)

2. The light detection element according to claim 1, wherein the focal point of the first lens is arranged to overlap with the first magnetic element when viewed from the optical axis direction of the first lens.

3. The light detection element according to claim 1, wherein the focal point of the second lens is arranged so as not to overlap with the first magnetic element when viewed from the optical axis direction of the second lens.

4. The light detection element according to claim 1, wherein the focal point of the second lens is arranged within a light spot formed on a plane on which the focal point of the first lens exists and perpendicular to the optical axis direction of the first lens.

5. The light detection element according to claim 1, wherein the first lens and the second lens are disposed on the same plane.

6. The light detection element according to claim 1, wherein the phase at the focal point of the first lens and the phase at the focal point of the second lens are different from each other.

7. The light detection element according to claim 1, wherein the phases at the focal points of the first lens and the second lens differ by 180 degrees.

8. The light detection element according to claim 1, wherein the first lens and the second lens are formed in different regions of a single lens.

9. A light detection element comprising:
a plurality of magnetic elements, each of which includes a first ferromagnetic layer, a second ferromagnetic layer, and a spacer layer sandwiched between the first ferromagnetic layer and the second ferromagnetic layer; and
a plurality of lenses, each of which irradiates light onto a corresponding one of the plurality of magnetic elements, wherein
the plurality of lenses are each made of a metalens having a plurality of nanostructures arranged two-dimensionally, and the size of the plurality of nanostructures in one of the adjacent lenses in a plan view seen from the optical axis direction of the one lens decreases as the distance from the optical center of the one lens increases in each region defined by the discontinuity points of equation (1) as boundaries, and the size of the plurality of nanostructures in the other of the adjacent lenses in a plan view seen from the optical axis direction of the other lens decreases as the distance from the optical center of the other lens increases in each region defined by the discontinuity points of equation (2) as boundaries.
$$ϕ ( r ) = - 2 π ( \frac{\sqrt{{f}^{2} + {( r - {a}_{1} )}^{2}} - f}{λ} - floor ( \frac{\sqrt{{f}^{2} + {( r - {a}_{1} )}^{2}} - f}{λ} ) ) \qquad ( 1 )$$
$$ϕ ( r ) = - 2 π ( \frac{\sqrt{{f}^{2} + {( r - {a}_{2} )}^{2}} - f}{λ} - floor ( \frac{\sqrt{{f}^{2} + {( r - {a}_{2} )}^{2}} - f}{λ} ) ) + Δϕ \qquad ( 2 )$$
(In the above equations (1) and (2), r is the distance from the origin, f is the focal length of the adjacent lenses, λ is the wavelength of the incident light, φ is the phase, a₁ is the distance from the origin to the optical center of the one lens, a₂ is the distance from the origin to the optical center of the other lens, A is the phase difference, and floor is the floor function.)

10. The light detection element according to claim 9, wherein the magnetic elements are arranged in a lattice pattern.

11. The light detection element according to claim 9, wherein the lenses are arranged in a lattice pattern.

12. The light detection element according to claim 9, wherein the focal point of at least one of the lenses is arranged to overlap the magnetic element corresponding to the lens when viewed from the optical axis direction of the lens.

13. The light detection element according to claim 9, wherein the focal point of at least one of the lenses is arranged so as not to overlap with any magnetic element other than the magnetic element to which light is irradiated by the lens, as viewed from the optical axis direction of the lens.

14. The light detection element according to claim 9, wherein the focal point of at least one of the lenses is arranged in a light spot formed on a plane on which the focal points of other adjacent lenses exist and perpendicular to the optical axis direction of the other lenses.

15. The light detection element according to claim 9, wherein at least two of the lenses are arranged on the same plane.

16. The light detection element according to claim 9, wherein at least two adjacent lenses of the plurality of lenses have phases at their respective focal points that differ from each other.

17. The light detection element according to claim 9, wherein at least two adjacent lenses of the plurality of lenses have phases at their respective focal points that differ by 180 degrees.

18. The light detection element according to claim 9, wherein at least two of the lenses are formed in different regions of one lens.

19. A communication system comprising a plurality of transceiver devices that transmit and receive optical signals, each of the transceiver devices including a receiver device having the light detection element according to claim 1.

20. The communication system according to claim 19, wherein the optical signal is a near-infrared light signal.
